(19) United States
(12) Patent Application Publication
(10) Pub. No.: US 2015/0357598 A1
(43) Pub. Date: Dec. 10, 2015

(54) ORGANIC ELECTROLUMINESCENCE DEVICE

(71) Applicant: NITTO DENKO CORPORATION, Ibaraki-shi, Osaka (JP)

(72) Inventors: Yoshinori Osaki, Ibaraki-shi (JP); Shigenori Morita, Ibaraki-shi (JP)

(73) Assignee: NITTO DENKO CORPORATION, Ibaraki-shi, Osaka (JP)

(21) Appl. No.: 14/760,552

(22) PCT Filed: Jan. 17, 2014
(86) PCT No.: PCT/JP2014/050759

§ 371 Date: Jul. 13, 2015

(30) Foreign Application Priority Data
Feb. 1, 2013 (JP) 2013-018836

(51) Int. Cl. H01L 51/52; H01L 51/50

(52) U.S. Cl. CPC H01L 51/5253; H01L 51/5012; H01L 51/5221; H01L 51/5206

(57) ABSTRACT

An organic EL device 1 includes first and second organic insulating layers 31, 32 on a conductive substrate 2, an inorganic insulating layer 33 on both organic insulating layers 31, 32, a first conductive layer 41 having a first terminal part 411 on the inorganic insulating layer, an organic EL layer 42 on the first conductive layer 41, and a second conductive layer 43 having a second terminal part 431 on the organic EL layer 42, wherein the first organic insulating layer 31 is disposed at the lower side of the first terminal part 411 via the inorganic insulating layer, the second organic insulating layer 32 is disposed at the lower side of the second terminal part 431 via the inorganic insulating layer, and respective inner end faces 31a, 32a and respective upper faces 31b, 32b of both organic insulating layers 31, 32 are covered with the inorganic insulating layer.

### TECHNICAL FIELD

The present invention relates to an organic electroluminescence device.

### BACKGROUND ART

In general, an organic electroluminescence device has a structure in which an organic electroluminescence element is laminated on a supporting substrate. The organic electroluminescence element has a first conductive layer, an organic electroluminescence layer, and a second conductive layer. In recent years, a technique for applying such an organic electroluminescence device to illuminating devices or the like has been studied. Hereinafter, “organic electroluminescence” is merely referred to as “organic EL”.

A moistureproof material such as glass and a metal has conventionally been used as a supporting substrate of the organic EL device. In the case where a conductive material such as a metal is used as a formation material for the supporting substrate, allowing the supporting substrate to conduct electricity flowing through an organic EL element (that is, allowing a short circuit to occur) needs to be prevented.

In order to prevent the short circuit, a technique for laminating an organic insulating layer containing a synthetic resin or an inorganic insulating layer containing a metal or a semimetal on a conductive supporting substrate (hereinafter, referred to as a conductive substrate) and laminating an organic EL element on the organic insulating layer or the inorganic insulating layer has been known (for example, Patent Documents 1 and 2).

However, although the organic insulating layer is excellent in smoothness, there is a problem that the organic insulating layer is poor in moistureproof properties. The organic EL element is easily deteriorated due to moisture. As such, in the case of using an organic insulating layer, there is a fear that an organic EL element is deteriorated due to moisture entering the inside of the organic insulating layer. When the organic EL element is deteriorated, there is a fear that stable light emission from an organic EL device cannot be maintained over a long period of time.

On the other hand, although the inorganic insulating layer is more satisfactory in moistureproof properties than the organic insulating layer, there is a problem that a micropore (a pinhole) or a crack is easily generated. When a large number of pinholes or cracks are generated in the inorganic insulating layer, since a short circuit easily occurs between an organic EL element and a conductive substrate through the pinholes or the cracks, there is a fear that stable light emission from an organic EL device cannot be maintained.

[Patent Document 1] JP 2003-282258 A

[Patent Document 2] JP 2002-25763 A

### SUMMARY OF THE INVENTION

An object of the present invention is to provide an organic EL device having sufficient moistureproof properties while preventing a short circuit from occurring between an organic EL element and a conductive substrate.

The present inventors have found that a short circuit easily occurs through pinholes generated in an inorganic insulating layer at the time of connecting an organic EL device and an external power source.

That is, the organic EL device has a first terminal part and a second terminal part at which a first conductive layer and a second conductive layer are exposed, respectively. Both terminal parts constitute parts connected to respective arbitrary connecting means (for example, lead wires or the like) for connecting an organic EL device and an external power source. The present inventors have found that a short circuit easily occurs between both terminal parts and a conductive substrate through pinholes existing in an inorganic insulating layer at the time of electrically connecting the respective connecting means and both terminal parts (for example, at the time of soldering).

Furthermore, the present inventors have conducted intensive researches in view of obtaining an insulating layer having both a merit of the organic insulating layer (high insulation properties) and a merit of the inorganic insulating layer (high moistureproof properties).

Specifically, first, the present inventors prepared an organic EL device 1A illustrated in FIG. 7 and conducted studies on the moistureproof properties of this organic EL device 1A and the occurrence frequency of the short circuit.

The organic EL device 1A illustrated in FIG. 7 has an organic insulating layer 31A formed on the whole upper face of a conductive substrate 2A and an inorganic insulating layer 33A further formed on the whole upper face of the organic insulating layer 31A. That is, the organic EL device 1A has an insulating layer 3A with a two-layer structure composed of the organic insulating layer 31A and the inorganic insulating layer 33A.

However, as described above, there is a case where pinholes are generated in the inorganic insulating layer 33A. As such, there is a fear that moisture entering the inside of the organic insulating layer 31A is brought into contact with an organic EL element through pinholes generated in the inorganic insulating layer 33A. Accordingly, even when the insulating layer 3A with a two-layer structure in which the inorganic insulating layer 33A is wholly laminated on the organic insulating layer 31A and the organic insulating layer 31A is wholly laminated on the conductive substrate 2A as mentioned above is used, the moistureproof properties of the organic EL device 1A have been insufficient.

Under these findings, the present inventors have found that the above problems can be solved by the following means.

The organic EL device of the present invention includes a conductive substrate, a first organic insulating layer and a second organic insulating layer which are disposed on the conductive substrate, an inorganic insulating layer disposed on the first organic insulating layer and the second organic insulating layer, a first conductive layer disposed on the inorganic insulating layer, an organic EL layer disposed on the first conductive layer, and a second conductive layer disposed on the organic EL layer, wherein the first conductive layer has a first terminal part which is positioned at an outer side of the organic EL layer and connected to an external power source, the second conductive layer has a second terminal part which is positioned at an outer side of the organic EL layer and connected to an external power source, the first organic insulating layer is disposed at a lower side of the first terminal part via the inorganic insulating layer, the second organic insulating layer is disposed at a lower side of the second terminal part via the inorganic insulating layer, and respective inner end faces and respective upper faces of the first organic insulating layer and the second organic insulating layer are covered with the inorganic insulating layer.

In a preferable organic EL device of the present invention, the first organic insulating layer and the second organic insulating layer each are independently disposed on the conductive substrate.

In a preferable organic EL device of the present invention, the inorganic insulating layer further covers respective outer end faces of the first organic insulating layer and the second organic insulating layer. Furthermore, it is more preferable that the first conductive layer is an anode layer and the second conductive layer is a cathode layer.

In a preferable organic EL device of the present invention, the inorganic insulating layer contains at least one kind of a metal and a semimetal, and at least one kind of the metal and the semimetal is selected from the group consisting of an oxide, a nitride, a carbide, a nitride oxide, a carbide oxide, a carbide nitride, and a carbide nitride oxide.

Furthermore, it is more preferable that the first organic insulating layer and the second organic insulating layer contain at least one kind selected from the group consisting of an acrylic resin, a norbornene resin, an epoxy resin, and a polyimide resin.

According to the present invention, an organic EL device having sufficient moistureproof properties while preventing a short circuit from occurring between an organic EL element and a conductive substrate is provided.

### BRIEF DESCRIPTION OF THE DRAWINGS

FIG. 1 is a plan view of an organic EL device according to one embodiment of the present invention.

FIG. 2 is an enlarged sectional view taken along the line II-II of the organic EL device in FIG. 1.

FIG. 3 is a referential plan view of an organic EL device according to a first embodiment of the present invention.

FIG. 4 is an enlarged sectional view of an organic EL device according to a second embodiment of the present invention.

FIG. 5 is a referential plan view of an organic EL device according to a first modified example of the present invention.

FIG. 6 is an enlarged sectional view of an organic EL device according to a second modified example of the present invention.

FIG. 7 is an enlarged sectional view of an organic EL device according to comparative examples 8 to 10.

Hereinafter, the present invention will be described with reference to the drawings. It should be noted that dimensions such as a layer thickness and a length in the drawings are different from actual dimensions. In this specification, the terms “first” and “second” may be added as prefixes. These prefixes, however, are only added in order to distinguish the terms and do not have specific meaning such as order and relative merits.

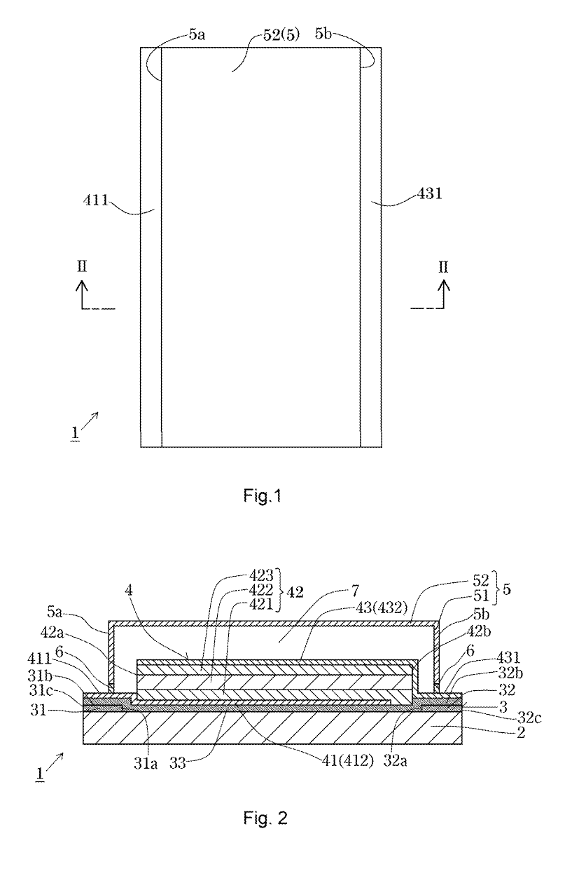

Furthermore, in the present specification, for convenience, “top direction” refers to the upper side and “bottom direction” refers to the lower side, with respect to the organic EL device 1 placed on a horizontal plane as illustrated in FIG. 2. Moreover, “inner side” refers to a side facing the in-plane center part on the upper face of the conductive substrate and “outer side” refers to a side facing the peripheral edge on the upper face of the conductive substrate.

FIG. 1 is a plan view illustrating an organic EL device 1 in accordance with the first embodiment of the present invention, and FIG. 2 is an enlarged sectional view thereof.

In this connection, although a plan-view substantially belt-shaped organic EL device 1 is used in the present embodiment, the plan-view shape of the organic EL device 1 is not particularly limited in the present invention.

Although the dimensions of the plan-view substantially belt-shaped organic EL device 1 are not particularly limited, in general, the ratio of width length of the organic EL device 1 is 1:3 to 1:20 and preferably 1:3 to 1:10.

As illustrated in FIG. 1 and FIG. 2, the organic EL device 1 according to the present invention has a conductive substrate 2, an insulating layer 3, an organic EL element 4, and a sealing member 5.

The organic EL element 4 has an organic EL layer 42, a first conductive layer 41, and a second conductive layer 43. The sealing member 5 is a member with which the organic EL layer 42 is sealed so as not to be exposed to the outside air and not to be brought into contact with moisture.

The first conductive layer 41 has a first electrode part 412 positioned at the lower side of the organic EL layer 42 and a first terminal part 411 positioned at the outer side of the organic EL layer 42. The second conductive layer 43 has a second electrode part 432 positioned at the upper side of the organic EL layer 42 and a second terminal part 431 positioned at the outer side of the organic EL layer 42. Both terminal parts 411, 431 constitute parts which are parts of the first and second conductive layers 41, 43 and receive electricity supplied from an external power source. Specifically, both terminal parts 411, 431 constitute parts which are parts of both conductive layers 41, 43 and are exposed to the outside air.

As illustrated in FIG. 1, the first and second terminal parts 411, 431 are disposed at both end parts in the widthwise direction of the organic EL device 1, respectively. Moreover, both terminal parts 411, 431 are disposed in a belt shape from one end part in the lengthwise direction to the other end part in the lengthwise direction of the organic EL device 1, respectively.

To the first terminal part 411 and the second terminal part 431, respective connecting means such as lead wires are connected (not illustrated). The connecting means is further connected to an external power source (not illustrated), and electricity supplied from the external power source is supplied to each of the first terminal part 411 and the second terminal part 431 through the connecting means. By allowing electricity to flow through both terminal parts 411, 431, a light emitting layer 422 contained in the organic EL layer 42 emits light.

Since the conductive substrate 2 is used in the present invention, allowing the organic EL element 4 and the conductive substrate 2 to conduct electricity (that is, allowing a short circuit to occur) needs to be prevented.

In the present invention, in order to prevent the short circuit, the insulating layer 3 is disposed. As illustrated in FIG. 2, the insulating layer 3 is laminated on the conductive substrate 2, and the organic EL element 4 is laminated on the insulating layer 3. In this way, by allowing the organic EL element 4 to be laminated on the conductive substrate 2 via the insulating layer 3, a short circuit caused by allowing the conductive substrate 2 to conduct the electricity flowing through the first terminal part 411 and the second terminal part 431 can be prevented.

Hereinafter, the constitution of each part of the organic EL device according to the present invention will be described.

### [Conductive Substrate]

The conductive substrate is a substrate on which an insulating layer and an organic EL element are laminated and has conductivity.

The formation materials for the conductive substrate are not particularly limited, and any materials having conductivity are used. Examples of such a material include a metal, a conductive resin, and the like. The conductive resin is one that allows the resin itself to have conductivity, a resin mixed with metal powder such as silver and copper and carbon such as carbon black, or the like. Examples of a resin having conductivity in itself include polypyrrole, polythiophene, polyacetylene, polyphenylene, polyphenylene vinylene, polyaniline, polyacene, polythiophene vinylene, an alloy resin thereof, and the like.

Preferably, it is preferred that the formation material for the conductive substrate be a metal processable into a film-like shape at ordinary temperature and normal pressure. Examples of such a metal include stainless steel, iron, aluminum, nickel, cobalt, copper, an alloy thereof, and the like.

Moreover, although the thickness of the conductive substrate is not particularly limited, but it is preferably 10 μm to 100 μm, more preferably 20 μm to 50 μm. The thinner the thickness of the conductive substrate is, the lighter in weight and the more flexible the organic EL device becomes.

### [Organic EL Element]

The organic EL element 4 has a first conductive layer 41, an organic EL layer 42, and a second conductive layer 43 which are laminated on an insulating layer 3 in this order. A part of the first conductive layer 41 positioned at the lower side of the organic EL layer 42 constitutes a first electrode part 412, and a part of the second conductive layer 43 positioned at the upper side of the organic EL layer 42 constitutes a second electrode part 432. That is, the organic EL layer 42 is sandwiched between both electrode parts 412, 432. Parts which are parts of the first and second conductive layers 41, 43 and are connected to an external power source constitute the first and second terminal parts 411, 431.

In this connection, in the present embodiment, the first conductive layer 41 is an anode layer, and the second conductive layer 43 is a cathode layer. Thus, the first terminal part 411 is an anode terminal, the first electrode part 412 is an anode part, the second terminal part 431 is a cathode terminal, and the second electrode part 432 is a cathode part. However, the present invention is not limited to the present embodiment, and the first conductive layer 41 and the second conductive layer 43 may be a cathode layer and an anode layer, respectively. In this case, the first terminal part 411 is a cathode terminal, the first electrode part 412 is a cathode part, the second terminal part 431 is an anode terminal, and the second electrode part 432 is an anode part.

An organic EL layer is a laminate composed of at least two function layers. Examples of a structure of the organic EL layer include (A) a structure composed of three layers including a positive hole transport layer, a light emitting layer, and an electron transport layer; (B) a structure composed of two layers including a positive hole transport layer and a light emitting layer; and (C) a structure composed of two layers including a light emitting layer and an electron transport layer. In the organic EL layer of the above-mentioned (B), the light emitting layer also works as an electron transport layer. In the organic layer of the above-mentioned (C), the light emitting layer works as a positive hole transport layer.

The organic EL layer of the organic EL device according to the present invention may have any of structures of the above-mentioned (A) to (C). In this connection, all of the organic EL devices illustrated in FIG. 1 to FIG. 7 have a structure of (A). That is, the organic EL devices 1 illustrated in FIG. 1 to FIG. 7 have an organic EL layer 42 with a three-layer structure in which a positive hole transport layer 421, a light emitting layer 422, and an electron transport layer 423 are laminated in the order from the bottom.

The positive hole transport layer 421 contained in the organic EL layer 42 has a function of injecting holes into the light emitting layer 422, and the electron transport layer 423 has a function of injecting electrons into the light emitting layer 422.

When electricity is allowed to flow through the first and second terminal parts 411, 431, the electrons and the holes injected into the light emitting layer 422 from the first and second electrode parts 412, 432 respectively are recombined to generate excited atoms (excitons). When the excitons return to the ground state, the light emitting layer 422 emits light.

Hereinafter, the first conductive layer 41 (anode layer), the positive hole transport layer 421, the light emitting layer 422, the electron transport layer 423, and the second conductive layer 43 (cathode layer) which the organic EL element 4 has will be described.

An anode layer (the first conductive layer of the present embodiment) is composed of a film having conductivity.

The formation material for the anode layer is not particularly limited, but examples include indium tin oxide (ITO); indium tin oxide including silicon oxide (ITSO); aluminum; gold; platinum; nickel; tungsten; copper; and an alloy. A thickness of the anode layer is not particularly limited, but it is usually 0.01 μm to 1.0 μm.

As the formation method of the anode layer, an optimum method can be employed depending on the formation material, and examples of the method include a sputtering method, a vapor deposition method, and an ink-jet method. For example, when the anode layer is formed using a metal, the vapor deposition method can be used.

The positive hole transport layer is disposed on the upper face of the anode layer. The positive hole transport layer has a function of injecting holes in the light emitting layer.

A formation material for the positive hole transport layer is not particularly limited as long as the formation material has a positive hole transport function. Examples of the formation material for the positive hole transport layer include an aromatic amine compound such as 4,4′,4″-tris(carbazole-9-yl)-triphenyl amine (abbreviation: TcTa); a carbazole derivative such as 1,3-bis(N-carbazolyl)benzene; a spiro compound such as N,N′-bis(naphthalene-1-yl)-N,N′-bis(phenyl)-9,9′-spiro-bisfluorene (abbreviation: Spiro-NPB); a polymer compound; and the like. The formation material for the positive hole transport layer may be used alone or in combination of two or more types. Furthermore, the positive hole transport layer may be a multi-layer structure having two or more layers.

A thickness of the positive hole transport layer is not particularly limited, but the thickness of 1 nm to 500 nm is preferable from the viewpoint of reducing drive voltage of the organic EL device.

Furthermore, as the formation method of the positive hole transport layer, an optimum method can be employed depending on the formation material, and examples of the method include a sputtering method, a vapor deposition method, an ink-jet method, and a coating method.

A light emitting layer is disposed on the upper face of the positive hole transport layer.

A formation material for the light emitting layer is not particularly limited as long as it has light emitting property. Examples of the formation material for the light emitting layer include a low molecular light emission material such as a low molecular fluorescence emission material, and a low molecular phosphorescence emission material.

Examples of the low molecular light emission material include an aromatic dimethylidene compound such as 4,4′-bis(2,2′-diphenyl vinyl)-biphenyl (abbreviation: DPVBi); an oxadiazole compound such as 5-methyl-2-[2-[4-(5-methyl-2-benzoxazolyl)phenyl]vinyl]benzoxazole; a triazole derivative such as 3-(4-biphenyl-yl)-4-phenyl-5-t-butyl phenyl-1,2,4-triazole; a styryl benzene compound such as 1,4-bis(2-methyl styryl)benzene; a benzoquinone derivative; a naphthoquinone derivative; an anthraquinone derivative; a fluorenone derivative; an organic metal complex such as an azomethine-zinc complex, tris(8-quinolinolato)aluminum (abbreviation: Alg₃), and the like.

A thickness of the light emitting layer is not particularly limited, but the thickness of 2 nm to 500 nm is preferable, for example.

Furthermore, as the formation method of the light emitting layer, an optimum method can be employed depending on the formation material, and it is usually formed by a vapor deposition method.

The electron transport layer is disposed on the upper face of the light emitting layer (the lower face of the cathode layer). The electron transport layer has a function of injecting electrons in the light emitting layer.

A formation material for the electron transport layer is not particularly limited as long as it is a material having an electron transport function. Examples of the formation material for the electron transport layer include a metal complex such as tris(8-quinolinolato)aluminum (abbreviation: Alg₃), bis(2-methyl-8-quinolinolato)(4-phenyl phenolate)aluminum (abbreviation: BAlq); a heteroaromatic compound such as 2,7-bis[2-(2,2′-bipyridine-6-yl)-1,3,4-oxadiazo-5-yl]-9,9-dimethyl fluorene (abbreviation: Bpy-FOXD), 2-(4-biphenylyl)-5-(4-tert-butyl phenyl)-1,3,4-oxadiazole (abbreviation: PBD), 1,3-bis[5-(p-tert-butyl phenyl)-1,3,4-oxadiazole-2-yl]benzene (abbreviation: OXD-7), and 2,2′,2″-(1,3,5-phenylene)-tris(1-phenyl-1H-benzimidazole) (abbreviation: TPBi); and a polymer compound such as poly(2,5-pyridine-diyl) (abbreviation: PPy). The formation material for the electron transport layer may be used alone or in combination of two or more types. Furthermore, the electron transport layer may have a multi-layered structure composed of two or more layers.

A thickness of the electron transport layer is not particularly limited, but the thickness of 1 nm to 500 nm is preferable from the viewpoint of reducing drive voltage of the organic EL device.

Furthermore, as the formation method of the electron transport layer, an optimum method can be employed depending on the formation material, and examples of the method include a sputtering method, a vapor deposition method, an ink-jet method, and a coating method.

The cathode layer (the second conductive layer of the present embodiment) is a film having conductivity.

A formation material for the cathode layer is not particularly limited. Examples of the formation material for the cathode layer which has conductivity include indium tin oxide (ITO); indium tin oxide including silicon oxide (ITSO); zinc oxide in which electric conductive metal such as aluminum is added (ZnO:Al); and a magnesium-silver alloy, and the like. A thickness of the cathode layer is not particularly limited, but it is usually 0.01 μm to 1.0 μm.

As the formation method of the cathode layer, an optimum method can be employed depending on the formation material, and examples of the method include a sputtering method, a vapor deposition method, an ink-jet method. For example, the sputtering method is used when the cathode layer is formed of ITO and the vapor deposition method is used when the cathode layer is formed of the laminated film of a magnesium-silver alloy or a magnesium-silver.

### [Insulating Layer]

On the whole lower face of the organic EL element, an insulating layer is disposed with no space between. By the insulating layer, allowing the organic EL element and the conductive substrate to be brought into contact with each other and allowing a short circuit to occur are prevented. The insulating layer has an organic insulating layer and an inorganic insulating layer.

The organic insulating layer is a layer containing an insulative synthetic resin as its main component. The inorganic insulating layer is a layer containing an insulative inorganic substance as its main component and having moistureproof properties.

In this connection, “containing an insulative synthetic resin as its main component” means containing an insulative synthetic resin at the largest proportion (mass) in the whole resin component of the organic insulating layer, and the case of containing other components (for example, an insulative inorganic substance) within the range of not impairing the function of the organic insulating layer is also included as well as the case where the organic insulating layer is composed only of an insulative synthetic resin. The same holds true for the inorganic insulating layer.

The organic insulating layer has a first organic insulating layer disposed at the lower side of the first terminal part, and a second organic insulating layer which is disposed at the lower side of the second terminal part and is discontinuous with the first organic insulating layer.

In FIG. 2, a first organic insulating layer 31 is disposed at the first side end part on the upper face of the conductive substrate 2 and a second organic insulating layer 32 is disposed at the second side end part on the upper face of the conductive substrate 2. In this way, both organic insulating layers 31, 32 each are independently disposed on areas which are positioned on the top (upper face) of the conductive substrate 2 and are spatially separated from each other.

The first and second organic insulating layers 31, 32 exist at the lower sides of the first and second terminal parts 411, 431, respectively. In other words, the first terminal part 411 is disposed so as to be overlapped with the first organic insulating layer 31 when planarly viewed and the second terminal part 431 is disposed so as to be overlapped with the second organic insulating layer 32 when planarly viewed.

In FIG. 2, the first and second terminal parts 411, 431 are disposed on the first and second organic insulating layers 31, 32 respectively so that the first and second terminal parts 411, 431 and the first and second organic insulating layers 31, 32 are indirectly overlapped with each other via an inorganic insulating layer 33 which is brought into close contact with the respective lower faces of the first and second terminal parts 411, 431.

Since there are few pinholes in the first and second organic insulating layers 31, 32, it is possible to prevent a short circuit from occurring between each of the first and second terminal parts 411, 431 and the conductive substrate 2 at the time of connecting the first and second terminal parts 411, 431 to respective connecting means.

The inorganic insulating layer 33 is disposed at the respective lower sides of the first electrode part 412 of the first conductive layer 41 and the first and second terminal parts 411, 431. In other words, the inorganic insulating layer 33 is disposed on a portion which is positioned on the upper face of the conductive substrate 2 and on which the first and second organic insulating layers 31, 32 are not disposed, and on the respective upper faces of the first and second organic insulating layers 31, 32.

Furthermore, the inorganic insulating layer 33 covers respective inner end faces 31a, 32a and respective upper faces 31b, 32b of both organic insulating layers 31, 32 with no space between. Specifically, as illustrated in FIG. 2, the inorganic insulating layer 33 is brought into close contact with the lower face of the first terminal part 411, and the first organic insulating layer 31 is brought into close contact with the lower face of the inorganic insulating layer 33. Moreover, the inorganic insulating layer 33 is brought into close contact with the lower face of the second terminal part 431, and the second organic insulating layer 32 is brought into close contact with the lower face of the inorganic insulating layer 33.

In this way, an insulating layer 3 having a two-layer structure is formed at the lower sides of both terminal parts 411, 431. In other words, respective inner end faces 31a, 32a and respective upper faces 31b, 32b of both organic insulating layers 31, 32 are sealed with the inorganic insulating layer 33.

In FIG. 1 and FIG. 2, respective outer end faces 31c, 32c of both organic insulating layers 31, 32 are exposed to the outside air. As such, there is a fear that moisture enters the both organic insulating layers 31, 32 through the respective outer end faces 31c, 32c. However, since respective inner end faces 31a, 32a and respective upper faces 31b, 32b of both organic insulating layers 31, 32 are covered with the inorganic insulating layer 33 excellent in moistureproof properties with no space between, even if moisture enters the inside of both organic insulating layers 31, 32, the moisture is blocked by the inorganic insulating layer 33 and can be suppressed from entering the inside of the organic EL element 4.

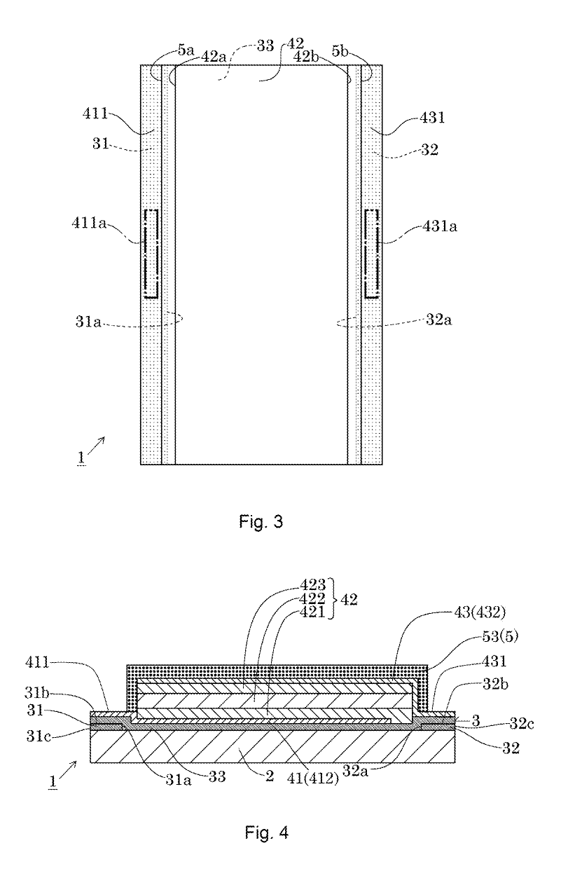

Hereinafter, the positional relationship of the first and second organic insulating layers 31, 32, the inorganic insulating layer 33, the first and second terminal parts 411, 431, the sealing member 5, and the organic EL layer 42 will be described in detail with reference to FIG. 2 and FIG. 3. Of course, in the present invention, the positional relationship of these members and parts is not limited to the embodiment of FIG. 2 and FIG. 3 and can be appropriately changed.

FIG. 3 is a plan view schematically representing the arrangement of the above-mentioned members and parts in the organic EL device in accordance with the present embodiment. In FIG. 3, in order to illustrate the positional relationship of the above-mentioned members and parts, for convenience, the first and second side edges 42a, 42b of the organic EL layer 42 are indicated by solid lines. Moreover, with regard to the insulating layer 3, areas where two layers of each of the first and second organic insulating layers 31, 32 and the inorganic insulating layer 33 exist are provided with a dot pattern composed of countless dots, and areas other than those (areas where only one layer of the inorganic insulating layer 33 exists and organic insulating layers 31, 32 do not exist) are unpatterned. In this connection, for convenience, in FIG. 3, lead lines for reference signs showing both organic insulating layers 31, 32, respective inner end faces 31a, 32a of both organic insulating layers 31, 32, and the inorganic insulating layer 33 are indicated by broken lines.

Moreover, within the respective upper faces of the first and second terminal parts 411, 431, respective areas surrounded by a heavy alternate long and short dash line are estimated connection areas 411a, 431a where each of the first and second terminal parts 411, 431 and a connecting means are connected.

As illustrated in FIG. 2 and FIG. 3, each of the first and second organic insulating layers 31, 32 is disposed so as to be overlapped with the whole lower face side area of each of the first and second terminal parts 411, 431. Furthermore, the inner end face 31a of the first organic insulating layer 31 is positioned at the inner side of the first outer edge 5a of the sealing member 5 and at the outer side of the first side edge 42a of the organic EL layer 42, and the inner end face 32a of the second organic insulating layer 32 is positioned at the inner side of the second outer edge 5b of the sealing member 5 and at the outer side of the second side edge 42b of the organic EL layer 42.

Accordingly, the boundary between the inner end face 31a of the first organic insulating layer 31 and the inorganic insulating layer 33 is positioned in an area inside the first outer edge 5a of the sealing member 5 and outside the first side edge 42a of the organic EL layer 42, and the boundary between the inner end face 32a of the second organic insulating layer 32 and the inorganic insulating layer 33 is positioned in an area inside the second outer edge 5b of the sealing member 5 and outside the second side edge 42b of the organic EL layer 42.

In this connection, as illustrated in FIG. 3, although each of the first and second organic insulating layers 31, 32 is disposed so as to be overlapped with the whole lower face side area of each of the first and second terminal parts 411, 431, the present invention is not limited to the present embodiment, and both organic insulating layers 31, 32 need only to be disposed so as to be overlapped at least with respective estimated connection areas 411a, 431a. As such, the inner end face 31a of the first organic insulating layer 31 may be positioned at the outer side of the first outer edge 5a of the sealing member 5 as long as the inner end face 31a and the estimated connection area 411a are not overlapped with each other, and the inner end face 32a of the second organic insulating layer 32 may be positioned at the outer side of the second outer edge 5b of the sealing member 5 as long as the inner end face 32a and the estimated connection area 431a are not overlapped with each other.

Specifically, the inner end face 31a of the first organic insulating layer 31 may be disposed at the outer side of the first outer edge 5a of the sealing member 5 and at the inner side of the estimated connection area 411a, and the inner end face 32a of the second organic insulating layer 32 may be disposed at the outer side of the second outer edge 5b of the sealing member 5 and at the inner side of the estimated connection area 431a. In such a case, the boundary between the inner end face 31a of the first organic insulating layer 31 and the inorganic insulating layer 33 is positioned in an area outside the first outer edge 5a of the sealing member 5 and inside the estimated connection area 411a, and the boundary between the inner end face 32a of the second organic insulating layer 32 and the inorganic insulating layer 33 is positioned in an area outside the second outer edge 5b of the sealing member 5 and inside the estimated connection area 431a.

Even in such a case, since respective organic insulating layers 31, 32 are disposed so as to be overlapped at least with respective estimated connection areas 411a, 431a, it is possible to prevent a short circuit from occurring between each of the first and second terminal parts 411, 431 and the conductive substrate 2 at the time of connecting respective connection means to the first and second terminal parts 411, 431.

Furthermore, each of both inner end faces 31a, 32a may be disposed at the inner side of each of the first and second side edges 42a, 42b of the organic EL layer 42. That is, each of both organic insulating layers 31, 32 may be overlapped not only with each of both terminal parts 411, 431 but also partially with the organic EL layer 42. Of course, when each of both inner end faces 31a, 32a is positioned at the excessively inner side of each of the first and second side edges 42a, 42b of the organic EL layer 42, there is a fear that the possibility of causing moisture entering the inside of both organic insulating layers 31, 32 to be brought into contact with the organic EL element 4 becomes high.

Accordingly, it is preferred that each of both inner end faces 31a, 32a be disposed at the outer side of each of the first and second side edges 42a, 42b of the organic EL layer 42.

The insulative synthetic resin contained in the organic insulating layer is not particularly limited. Of course, since there is a case where an organic EL device is heated to 150° C. to 300° C. in view of restriction of the production process thereof, it is preferred that a heat-resistant synthetic resin having a glass transition temperature higher than or equal to 150° C. be used.

Examples of such a synthetic resin include an acrylic resin, a norbornene resin, an epoxy resin, a polyimide resin, a polyamide-imide resin, a polyamide resin, a polyester resin, a polyarylate resin, a polyurethane resin, a polycarbonate resin, a polyether ketone resin, a polyphenyl sulfone resin, a composite body of these resins, and the like.

The insulative synthetic resin is preferably at least one kind selected from the group consisting of an acrylic resin, a norbornene resin, an epoxy resin, and a polyimide resin.

The thickness of the organic insulating layer is not particularly limited. Of course, when the thickness of the organic insulating layer is too thin, there is a fear that the upper face of the conductive substrate cannot be sufficiently smoothed, and in addition, a short circuit cannot be sufficiently prevented. On the other hand, when the thickness of the organic insulating layer is too thick, there is a fear that the adhesive properties to the conductive substrate are lowered.

As such, the thickness of the organic insulating layer is preferably 1 μm to 40 μm, more preferably 0.5 μm to 20 μm, further preferably 0.5 μm to 10 μm, particularly preferably 1 μm to 5 μm.

When the thickness of the organic insulating layer lies within the above-mentioned range, it is possible to ensure sufficient electrical insulation properties and to ensure the adhesive properties to the conductive substrate.

Although the formation method of an organic insulating layer is not particularly limited, the application by roll coating, spray coating, spin coating, dipping or the like, patterning, and the transcription using a film-shaped synthetic resin can be employed.

Preferably, the organic insulating layer is formed by patterning. By allowing the organic insulating layer to be formed by patterning, it is possible to partially form an organic insulating layer in an arbitrary area on the conductive substrate.

As the patterning method, for example, methods such as photolithography, photoetching, a screen printing method, and an inkjet printing method can be used. Preferably, the patterning is performed by photolithography. The photolithography is preferred because the pattern precision is high and fine processing is facilitated.

The insulative inorganic substance contained in the inorganic insulating layer is not particularly limited. Such an insulative inorganic substance may be a metal, a semimetal, and a mixture of a metal and a semimetal.

Examples of the metal include zinc, aluminum, titanium, copper, magnesium and the like, and examples of the semimetal include silicon, bismuth, germanium and the like.

Moreover, preferably, at least one kind of the metal and the semimetal is at least one kind selected from the group consisting of an oxide, a nitride, a carbide, a nitride oxide, a carbide oxide, a carbide nitride, and a carbide nitride oxide.

The thickness of the inorganic insulating layer is not particularly limited. Of course, when the thickness of the inorganic insulating layer is too thin, there is a fear that a pinhole is easily generated, and the moistureproof properties and the insulation properties are lowered. Moreover, when the thickness of the inorganic insulating layer is too thick, there is a fear that a crack is easily generated, and the moistureproof properties and the insulation properties are lowered.

From such a viewpoint, the thickness of the inorganic insulating layer is preferably 10 nm to 5 μm, more preferably 50 nm to 2 μm, further preferably 0.1 μm to 1 μm, particularly preferably 0.3 μm to 0.5 μm.

When the thickness of the inorganic insulating layer lies within the above-mentioned range, it is possible to ensure sufficient insulation properties and to prevent a pinhole and a crack from being generated.

Although the formation method of an inorganic insulating layer is not particularly limited, a dry process such as a vapor deposition method, a sputtering method and a CVD method, a wet process such as a sol-gel method, or the like can be employed.

In this connection, in the present invention, in the case where the insulative inorganic substance is selected from the group consisting of a metal oxide, a metal nitride, a semimetal oxide, and a semimetal nitride, the inorganic insulating layer can be formed by allowing these inorganic substances (the vapor deposition source) to be vapor deposited in an atmosphere where arc discharge plasma is generated in the presence of a reactant gas.

As such a reactant gas, an oxygen-containing gas, a nitrogen-containing gas, a mixed gas thereof, or the like can be used. Examples of the oxygen-containing gas include oxygen (O₂) gas, dinitrogen monoxide (N₂O) gas, nitrogen monoxide (NO) gas and the like, and examples of the nitrogen-containing gas include nitrogen (N₂) gas, ammonia (NH₃) gas, nitrogen monoxide (NO) gas and the like. In this connection, nitrogen monoxide (NO) gas is an oxygen-containing gas and is also a nitrogen-containing gas.

In the case of forming an inorganic insulating layer by a vapor deposition method, as the means for evaporating an insulative inorganic substance (a vapor deposition source), resistive heating, an electron beam, or arc discharge plasma can be employed.

Of these, since high-speed vapor deposition is possible, it is preferred that an electron beam or arc discharge plasma be used. In this connection, two or more kinds of these means can be used in combination.

### [Sealing Member]

The sealing member is a member with which the organic EL layer is sealed. The constitution of the sealing member is not particularly limited. For example, in FIG. 2, the organic EL layer 42 is sealed with a glass sealing member 5 (a glass cap) having a cylindrical sidewall part 51 surrounding the periphery of the organic EL layer 42 and a ceiling part 52 covering the upper side of the organic EL layer 42. The ceiling part 52 is formed so that one opening part of a non-bottomed cylindrical sidewall part 51 is closed.

The sealing member 5 is bonded onto the first and second terminal parts 411, 431 via an adhesive agent layer 6 composed of an adhesive agent. That is, the organic EL layer 42 is hollow-sealed with the sealing member 5.

In this way, by allowing the periphery of the organic EL layer 42 to be hollow-sealed with the sealing member 5, the organic EL layer 42 is blocked off from moisture existing outside the sealing member 5 and the deterioration thereof can be prevented.

In this connection, a drying agent (not illustrated) may be placed in the space (the sealed space 7) between the sealing member 5 and the organic EL layer 42. By allowing the drying agent to be placed in the inside of the sealed space 7, even when moisture enters the inside of the sealed space 7, the moisture is absorbed before the moisture reaches the organic EL layer 42, and the deterioration of the organic EL layer 42 can be effectively prevented.

Moreover, the inside of the sealed space 7 may be filled with an inert gas such as helium gas and nitrogen gas.

The formation material for the adhesive agent layer is not particularly limited as long as the formation material has moistureproof properties. Preferably, the adhesive agent layer is formed from a resin having moistureproof properties.

Examples of such a resin include an epoxy resin, an acrylic resin, a polyester resin, a polyarylate resin, a polyurethane resin, and the like.

Of these, it is preferred that a two-pack curing type epoxy resin be used. Since the two-pack curing type epoxy resin is curable at ordinary temperature, it is unnecessary to heat the organic EL device in order to cure the resin. As such, the deterioration of the organic EL device can be effectively prevented.

Moreover, as illustrated in FIG. 4, the sealing member 5 may be a barrier layer 53 which is brought into close contact with the surface of the organic EL element 4. In this connection, the organic EL device 1 in FIG. 4 is the same as the organic EL device 1 in each of FIGS. 1 to 3 with the exception of the constitution of the sealing member 5.

The formation material for the barrier layer 53 is not particularly limited, and one that has moistureproof properties is used. In this connection, in FIG. 4, for convenience, the section of the barrier layer 53 is not provided with oblique lines, and alternatively, the section is provided with a dot pattern composed of countless dots.

As the formation material for the barrier layer, for example, silicon nitride (SiN), silicon carbide (SiC), silicon carbide oxide (SiOC), and an Si-containing nitride such as silicon carbide nitride oxide (SiOCN) are used.

The formation method of a barrier layer 53 is not particularly limited, and the same method as the formation method of an inorganic insulating layer can be employed. Preferably, the barrier layer 53 is formed by a vapor deposition method, and more preferably, the barrier layer 53 is formed by a plasma-assisted vapor deposition method.

Moreover, the thickness of the barrier layer 53 is not particularly limited, and the thickness is 0.2 μm to 50 μm, preferably 0.2 μm to 10 μm, and more preferably 0.2 μm to 2 μm.

Modified examples of the present invention will be described below. In this regard, configurations and effects different from those of the above-described embodiment will be described upon explanation of the following modified examples, and the same configurations and the like as those of the above-described embodiment will not be described and terms and reference numerals are employed in some cases.

### FIRST MODIFIED EXAMPLE

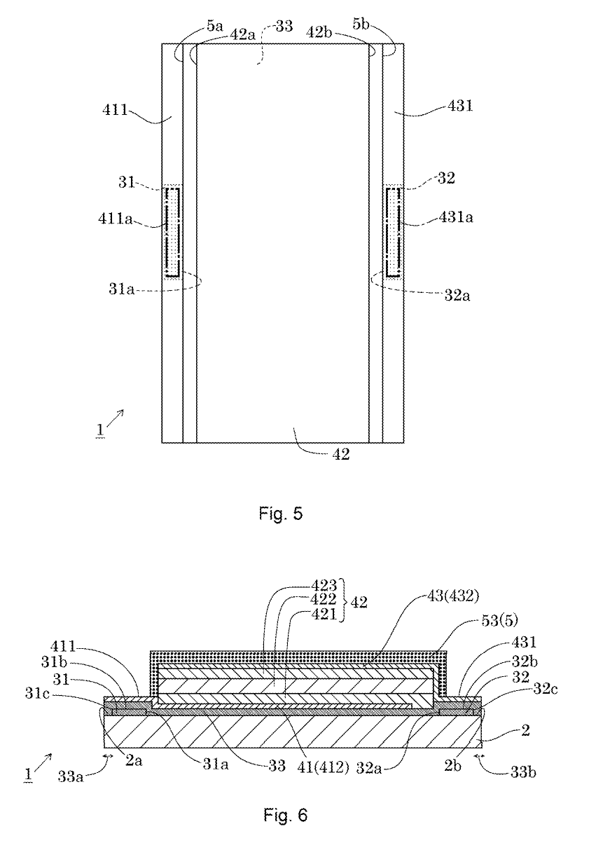

FIG. 5 is a referential plan view of an organic EL device 1 in accordance with the first modified example of the present invention. For the description of parts and members illustrated in FIG. 5, see those in FIG. 3 described above.

In the present modified example, respective two-layer portions (portions provided with a dot pattern) composed of each of both organic insulating layers 31, 32 and the inorganic insulating layer 33 are disposed on respective estimated connection areas 411a, 431a, and each of the two-layer portions has an area almost comparable to that of each of the estimated connection areas 411a, 431a. That is, in the present modified example, the two-layer portion composed of each of the first and second organic insulating layers 31, 32 and the inorganic insulating layer 33 is disposed so as to be overlapped almost only with each of the estimated connection areas 411a, 431a.

In the present modified example, since respective outer end faces 31c, 32c of both organic insulating layers 31, 32 are not significantly exposed to the outside air, moisture hardly enters the inside of both organic insulating layers 31, 32. And then, since at least each of both organic insulating layers 31, 32 is disposed so as to be overlapped at least with the whole lower face side area of each of the estimated connection areas 411a, 431a, it is possible to effectively prevent a short circuit from occurring between each of the estimated connection areas 411a, 431a and the conductive substrate 2.

### SECOND MODIFIED EXAMPLE

FIG. 6 is an enlarged sectional view illustrating an organic EL device 1 in accordance with the second modified example of the present invention.

In the present modified example, a first organic insulating layer 31 is disposed at a first side end part on the upper face of the conductive substrate 2, but a first organic insulating layer 31 is not disposed at the first side end on the upper face of the conductive substrate 2 and the vicinity 2a thereof. Moreover, a second organic insulating layer 32 is disposed at a second side end part on the upper face of the conductive substrate 2, but a second organic insulating layer 32 is not disposed at the second side end on the upper face of the conductive substrate 2 and the vicinity 2b thereof. And then, an inorganic insulating layer 33 is disposed at the first and second side ends of the conductive substrate 2 and the vicinities 2a, 2b thereof.

In the present modified example, respective inner end faces 31a, 32a, respective upper faces 31b, 32b, and respective outer end faces 31c, 32c of both organic insulating layers 31, 32 are covered with the inorganic insulating layer 33 with no space between. In other words, all the surfaces of both organic insulating layers 31, 32 excluding the lower faces thereof are sealed with the inorganic insulating layer 33.

In this way, since the respective outer end faces 31c, 32c of both organic insulating layers 31, 32 are covered with the inorganic insulating layer 33, it is possible to prevent moisture from entering the both organic insulating layers 31, 32 through the respective outer end faces 31c, 32c.

Moreover, in the present modified example, as illustrated in FIG. 3, the first and second organic insulating layers 31, 32 may be disposed not only at the estimated connection areas 411a, 431a but also at areas other than those, and as illustrated in FIG. 5, the first and second organic insulating layers 31, 32 may be disposed only at the respective lower sides of the estimated connection areas 411a, 431a.

The organic EL device according to the present invention is not limited to the foregoing embodiment, and the design can be variously changed within the intended scope of the present invention.

In the above-mentioned embodiment, although the insulating layer disposed at the lower side of the first terminal part and the insulating layer disposed at the lower side of the second terminal part are the same as each other in constitution, these insulating layers may be different from each other in constitution. For example, with regard to a first organic insulating layer disposed at the lower side of the first terminal part, like the embodiment described firstly, only the inner end face and upper face thereof may be covered with the inorganic insulating layer, and on the other hand, with regard to a second organic insulating layer disposed at the lower side of the second terminal part, like the above-mentioned second modified example, the inner end face, upper face and outer end face thereof may be covered with the inorganic insulating layer (not illustrated).

### EXAMPLES

The present invention will be described below with reference to Examples and Comparative Examples. The present invention is not limited only to the following Examples. Each of measuring methods used in the Examples and the Comparative Examples are as follows.

### <Measurement of Thickness of Insulating Layer>

The section of an organic EL device was observed with a scanning electron microscope (trade name “JSM-6610” available from JEOL Ltd.) and the thicknesses of the organic insulating layer and the inorganic insulating layer were measured.

### <Measurement of Occurrence Rate of Short Circuit>

With regard to organic EL devices in Examples and Comparative Examples, 20 pieces of each of those were prepared, and lead wires were connected to terminal parts of all the organic EL devices by soldering to allow a current to flow. On that occasion, the proportion of organic EL devices in which a current is allowed to flow between the lead wire and the conductive substrate (that is, a short circuit is allowed to occur) was calculated.

### <Measurement of Ratio of Light Emitting Area>

Each of organic EL devices in Examples and Comparative Examples was allowed to emit light, and the light emitting area before exposed to a high-temperature and high-humidity environment was measured with a digital microscope (trade name “VHX-1000” available from KEYENCE CORPORATION) to determine a light emitting area used as a basis.

Afterward, the organic EL devices in Examples and Comparative Examples were stored in a state of non-lighting under a high-temperature and high-humidity condition of a temperature of 60° C. and a relative humidity of 90% RH. After 500 hours, the organic EL device was allowed to emit light to measure a light emitting area thereof again. And then, based on the light emitting area before exposed to a high-temperature and high-humidity environment (100%), the ratio of the light emitting area of the organic EL device after exposed to a high-temperature and high-humidity environment was calculated.

### Example 1

### Formation of Insulating Layer

A stainless steel substrate (SUS304, 50 μm in thickness) as a conductive substrate was prepared. On the whole upper face of the stainless steel substrate, a norbornene resin (trade name “ZEOCOAT” available from Zeon Corporation) was coated by means of a wire bar and subjected to pre-baking for 5 minutes at 100° C. to form a one-layer organic insulating layer.

Afterward, a part excluding both side edge parts of the organic insulating layer was exposed, and an organic insulating layer corresponding to the exposed part was removed with a developing solution (an aqueous tetramethylammonium hydroxide solution). In this way, a first organic insulating layer was formed at one side end part of the conductive substrate and a second organic insulating layer was formed at the other side end part thereof.

Afterward, the first and second organic insulating layers formed were subjected to post-baking for 1 hour at 220° C. to be completely solidified. The thickness of each of the first and second organic insulating layers was 3.0 μm.

Afterward, on the upper face of the conductive substrate and on the upper faces of the first and second organic insulating layers, an inorganic insulating layer composed of an SiO₂ layer was formed by sputtering. The thickness of the inorganic insulating layer was 0.3 μm.

### (Formation of Organic EL Element)

On the obtained insulating layer, an Ag (silver)-made layer that constitutes an anode layer and has a thickness of 200 nm, an HAT-CN (1,4,5,8,9,12-hexaazatriphenylene hexacarbonitrile)-made layer that constitutes a positive hole injection layer and has a thickness of 10 nm, an NPB (N,N′-bis(naphthalene-1-yl)-N,N′-bis(phenyl)-benzidine)-made layer that constitutes a positive hole transport layer and has a thickness of 50 nm, an Alq (tris(8-quinolinolato)aluminum)-made layer that constitutes both a light emitting layer and an electron transport layer and has a thickness of 45 nm, an LiF (lithium fluoride)-made layer that constitutes an electron injection layer and has a thickness of 0.5 nm, and an Mg/Ag-made (co-vapor deposited) layer that constitutes a cathode layer and has thicknesses of 5/15 nm were vapor deposited under vacuum in this order. Furthermore, an ITO-made layer that has a thickness of 50 nm was deposited thereon by sputtering to form an organic EL element.

### (Formation of Sealing Member)

On the upper face of the organic EL element, an SiOCN-made layer that has a thickness of 1 μm was deposited by the plasma-assisted vapor deposition to prepare a thin film-shaped sealing member. In this connection, a sealing member was not deposited on each of the anode terminal and the cathode terminal (excluding portions near the organic EL layer).

The organic EL device thus obtained had a configuration illustrated in FIG. 4.

The organic EL device was measured for the occurrence rate of the short circuit and the ratio of the light emitting area according to the above-mentioned measuring methods. The results are shown in Table 1.

### Example 2

A stainless steel substrate (SUS304, 50 μm in thickness) as a conductive substrate was prepared. On the whole upper face of the stainless steel substrate, a mixed solution prepared by dissolving a fluorene derivative 1 (bisphenoxyethanol fluorene diglycidyl ether) of the following structural formula (I), a fluorene derivative 2 (bisphenol fluorene diglycidyl ether) of the following structural formula (II), and a photoacid generator as a catalyst (a 50% propioncarbide solution of 4,4-bis[di(β-hydroxyethoxy)phenylsulfinio]phenyl sulfide-bis-hexafluoroantimonate) in a solvent (cyclohexanone) was coated by means of a wire bar and subjected to pre-baking for 15 minutes at 90° C. to form a one-layer organic insulating layer.

Afterward, only both side edge parts of the organic insulating layer were exposed, and an organic insulating layer corresponding to the unexposed part was removed with a developing solution (acetonitrile). In this way, a first organic insulating layer was formed at one side end part of the conductive substrate and a second organic insulating layer was formed at the other side end part thereof.

Afterward, the first and second organic insulating layers formed were subjected to post-baking for 30 minutes at 170° C. to be completely solidified. The thickness of each of the first and second organic insulating layers was 3.0 μm.

Afterward, on the upper face of the conductive substrate and on the upper faces of the first and second organic insulating layers, an inorganic insulating layer composed of an SiO₂ layer was formed by sputtering. The thickness of the inorganic insulating layer was 0.3 μm.

The organic EL device thus obtained had a configuration illustrated in FIG. 4.

The organic EL device was measured for the occurrence rate of the short circuit and the ratio of the light emitting area according to the above-mentioned measuring methods. The results are shown in Table 1.

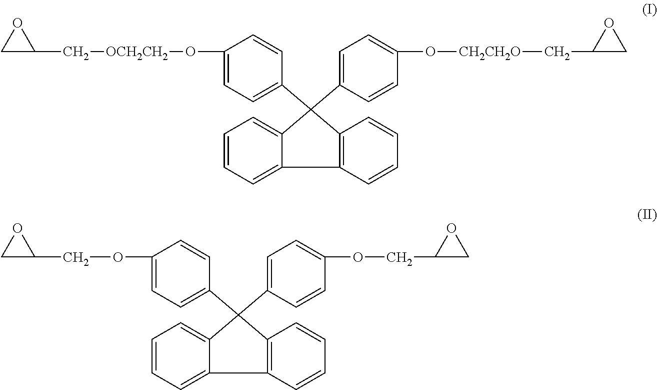

### Example 3

An organic EL device was prepared in the same manner as that in Example 1 except that an acrylic resin (trade name “JEM-477” available from JSR Corporation) was used in place of the norbornene-based resin. In this connection, the thickness of each of the first and second organic insulating layers was 3.0 μm, and the thickness of the inorganic insulating layer was 0.3 μm.

The organic EL device thus obtained had a configuration illustrated in FIG. 4.

The organic EL device was measured for the occurrence rate of the short circuit and the ratio of the light emitting area according to the above-mentioned measuring methods. The results are shown in Table 1.

### Comparative Example 1

An organic EL device in accordance with Comparative Example 1 was prepared in the same manner as that in Example 1 except that an organic insulating layer was not formed. That is, the organic EL device in Comparative Example 1 has an insulating layer composed only of an inorganic insulating layer disposed on the whole upper face of the conductive substrate. In this connection, the thickness of the inorganic insulating layer was 0.3 μm.

The organic EL device was measured for the occurrence rate of the short circuit and the ratio of the light emitting area according to the above-mentioned measuring methods. The results are shown in Table 1.

### Comparative Example 2

An organic EL device in accordance with Comparative Example 2 was prepared in the same manner as that in Comparative Example 1 except that the thickness of the inorganic insulating layer was set to 0.1 μm.

The organic EL device was measured for the occurrence rate of the short circuit and the ratio of the light emitting area according to the above-mentioned measuring methods. The results are shown in Table 1.

### Comparative Example 3

An organic EL device in accordance with Comparative Example 3 was prepared in the same manner as that in Comparative Example 1 except that the thickness of the inorganic insulating layer was set to 0.5 μm.

The organic EL device was measured for the occurrence rate of the short circuit and the ratio of the light emitting area according to the above-mentioned measuring methods. The results are shown in Table 1.

### Comparative Example 4

An organic EL device in accordance with Comparative Example 4 was prepared in the same manner as that in Comparative Example 1 except that the thickness of the inorganic insulating layer was set to 1.0 μm.

The organic EL device was measured for the occurrence rate of the short circuit and the ratio of the light emitting area according to the above-mentioned measuring methods. The results are shown in Table 1.

### Comparative Example 5

An organic EL device in accordance with Comparative Example 5 was prepared in the same manner as that in Example 1 except that patterning of the organic insulating layer composed of the norbornene resin was not performed and an inorganic insulating layer was not formed. That is, the organic EL device in accordance with Comparative Example 5 has an insulating layer composed only of a norbornene resin layer disposed on the whole upper face of the conductive substrate. In this connection, the thickness of the organic insulating layer was 3.0 μm.

The organic EL device was measured for the occurrence rate of the short circuit and the ratio of the light emitting area according to the above-mentioned measuring methods. The results are shown in Table 1.

### Comparative Example 6

An organic EL device in accordance with Comparative Example 6 was prepared in the same manner as that in Example 2 except that patterning of the organic insulating layer composed of the epoxy resin was not performed and an inorganic insulating layer was not formed. That is, the organic EL device in accordance with Comparative Example 6 has an insulating layer composed only of an epoxy resin layer disposed on the whole upper face of the conductive substrate. In this connection, the thickness of the organic insulating layer was 3.0 μm.

The organic EL device was measured for the occurrence rate of the short circuit and the ratio of the light emitting area according to the above-mentioned measuring methods. The results are shown in Table 1.

### Comparative Example 7

An organic EL device in accordance with Comparative Example 7 was prepared in the same manner as that in Example 3 except that patterning of the organic insulating layer composed of the acrylic resin was not performed and an inorganic insulating layer was not formed. That is, the organic EL device in accordance with Comparative Example 7 has an insulating layer composed only of an acrylic resin layer disposed on the whole upper face of the conductive substrate. In this connection, the thickness of the organic insulating layer was 3.0 μm.

The organic EL device was measured for the occurrence rate of the short circuit and the ratio of the light emitting area according to the above-mentioned measuring methods. The results are shown in Table 1.

### Comparative Example 8

An organic EL device in accordance with Comparative Example 8 was prepared in the same manner as that in Example 1 except that patterning of the organic insulating layer composed of the norbornene resin was not performed. That is, the organic EL device in accordance with Comparative Example 8 has an insulating layer with a two-layer structure composed of an organic insulating layer disposed on the whole upper face of the conductive substrate and an inorganic insulating layer disposed on the whole upper face of the organic insulating layer. In this connection, the thickness of the organic insulating layer was 3.0 μm, and the thickness of the inorganic insulating layer was 0.3 μm.

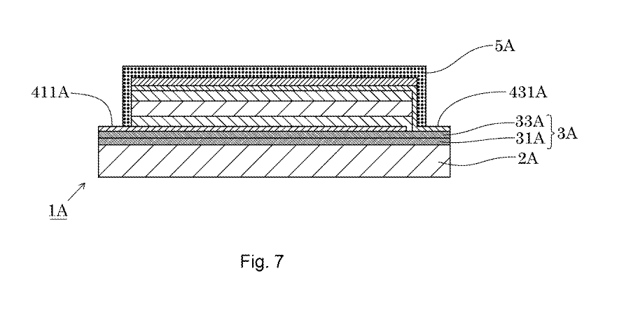

The organic EL device thus obtained had a configuration illustrated in FIG. 7.

The organic EL device was measured for the occurrence rate of the short circuit and the ratio of the light emitting area according to the above-mentioned measuring methods. The results are shown in Table 1.

### Comparative Example 9

An organic EL device in accordance with Comparative Example 9 was prepared in the same manner as that in Example 2 except that patterning of the organic insulating layer composed of the epoxy resin was not performed. That is, the organic EL device in accordance with Comparative Example 9 has an insulating layer with a two-layer structure composed of an organic insulating layer disposed on the whole upper face of the conductive substrate and an inorganic insulating layer disposed on the whole upper face of the organic insulating layer. In this connection, the thickness of the organic insulating layer was 3.0 μm, and the thickness of the inorganic insulating layer was 0.3 μm.

The organic EL device thus obtained had a configuration illustrated in FIG. 7.

The organic EL device was measured for the occurrence rate of the short circuit and the ratio of the light emitting area according to the above-mentioned measuring methods. The results are shown in Table 1.

### Comparative Example 10

An organic EL device in accordance with Comparative Example 10 was prepared in the same manner as that in Example 3 except that patterning of the organic insulating layer composed of the acrylic resin was not performed. That is, the organic EL device in accordance with Comparative Example 10 has an insulating layer with a two-layer structure composed of an organic insulating layer disposed on the whole upper face of the conductive substrate and an inorganic insulating layer disposed on the whole upper face of the organic insulating layer. In this connection, the thickness of the organic insulating layer was 3.0 μm, and the thickness of the inorganic insulating layer was 0.3 μm.

The organic EL device thus obtained had a configuration illustrated in FIG. 7.

The organic EL device was measured for the occurrence rate of the short circuit and the ratio of the light emitting area according to the above-mentioned measuring methods. The results are shown in Table 1.

TABLE 1

| | Configuration of Insulating Layer | | | | Occurrence Rate | |
|---|---|---|---|---|---|---|
| | | Thickness | Inorganic | Thickness | of | Ratio of Light-emitting |
| | Organic Insulating Layer | (μm) | Insulating Layer | (μm) | Short Circuit (%) | Area (%) |
| Example 1 | Norbornene Resin (patterning) | 3.0 μm | SiO₂ (whole face) | 0.3 μm | 0 | 100 |
| Example 2 | Epoxy Resin (patterning) | 3.0 μm | SiO₂ (whole face) | 0.3 μm | 0 | 100 |
| Example 3 | Acrylic Resin (patterning) | 3.0 μm | SiO₂ (whole face) | 0.3 μm | 0 | 95 |
| Comparative | None | | SiO₂ (whole face) | 0.3 μm | 60 | 100 |
| Example 1 | | | | | | |
| Comparative | None | | SiO₂ (whole face) | 0.1 μm | 90 | 80 |
| Example 2 | | | | | | |
| Comparative | None | | SiO₂ (whole face) | 0.5 μm | 60 | 100 |
| Example 3 | | | | | | |
| Comparative | None | | SiO₂ (whole face) | 1.0 μm | 80 | 100 |
| Example 4 | | | | | | |
| Comparative | Norbornene Resin (whole face) | 3.0 μm | None | | 0 | 30 |
| Example 5 | | | | | | |
| Comparative | Epoxy Resin (whole face) | 3.0 μm | None | | 0 | 30 |
| Example 6 | | | | | | |
| Comparative | Acrylic Resin (whole face) | 3.0 μm | None | | 0 | 25 |
| Example 7 | | | | | | |
| Comparative | Norbornene Resin (whole face) | 3.0 μm | SiO₂ (whole face) | 0.3 μm | 0 | 70 |
| Example 8 | | | | | | |
| Comparative | Epoxy Resin (whole face) | 3.0 μm | SiO₂ (whole face) | 0.3 μm | 0 | 70 |
| Example 9 | | | | | | |
| Comparative | Acrylic Resin (whole face) | 3.0 μm | SiO₂ (whole face) | 0.3 μm | 0 | 70 |
| Example 10 | | | | | | |

### [Evaluation]

As shown in Table 1, in organic EL devices of Examples 1 to 3, a short circuit has not occurred at all between the terminal part to which a lead wire is connected and the conductive substrate. Moreover, the ratio of the light emitting area has hardly changed between before and after exposed to a high-temperature and high-humidity environment. It is thought that this is because moisture entering the organic insulating layer through the outer end face is blocked by the inorganic insulating layer and the moisture does not reach the organic EL layer.

On the other hand, in organic EL devices of Comparative Examples 1 to 4, the ratio of the light emitting area has not changed much between before and after exposed to a high-temperature and high-humidity environment, but very high values of the occurrence rate of the short circuit lying within the range of 60 to 90% are exhibited. With regard to Comparative Example 2, it is thought that a large number of pinholes are generated since the thickness of the inorganic insulating layer, which is 0.1 μm, is very thin, and this causes a short circuit to occur. And then, it has been found that the thicker the film thickness of the inorganic insulating layer is, the more hardly generated the pinholes are, and the short circuit can be prevented. However, when the film thickness is greater than 0.5 μm, the occurrence rate of the short circuit has increased again. It is thought that this is because a crack is generated in an inorganic insulating layer when the inorganic insulating layer is too thick, and the crack causes a short circuit to occur.

Moreover, in organic EL devices of Comparative Examples 5 to 7, the short circuit can be completely prevented from occurring, but the light emitting area has greatly decreased after exposed to a high-temperature and high-humidity environment. It is thought that this is because moisture enters the organic insulating layer through the outer end face, and the moisture which has reached the organic EL element deteriorates the organic EL element.

Furthermore, in organic EL devices of Comparative Examples 8 to 10, the short circuit can be completely prevented from occurring, but the light emitting area cannot be sufficiently suppressed from decreasing. It is thought that this is because moisture entering the organic insulating layer through the outer end face has reached the organic EL element through pinholes or cracks in the inorganic insulating layer.

### INDUSTRIAL APPLICABILITY

The organic EL device of the present invention can be used for illuminating devices and the like.

1 Organic EL device, 2 Conductive substrate, 3 Insulating layer, 31 First organic insulating layer, 31a Inner end face of first organic insulating layer, 31b Upper face of first organic insulating layer, 32 Second organic insulating layer, 32a Inner end face of second organic insulating layer, 32b Upper face of second organic insulating layer, 33 Inorganic insulating layer, 4 Organic EL element, 41 First conductive layer, 411 First terminal part, 42 Organic EL layer, 43 Second conductive layer, 431 Second terminal part, 5 Sealing member, 51 Side wall part, 52 Ceiling part, 6 Adhesive agent layer

1. An organic electroluminescence device, comprising:
a conductive substrate;
a first organic insulating layer and a second organic insulating layer which are disposed on the conductive substrate;
an inorganic insulating layer disposed on the first organic insulating layer and the second organic insulating layer;
a first conductive layer disposed on the inorganic insulating layer;
an organic electroluminescence layer disposed on the first conductive layer; and
a second conductive layer disposed on the organic electroluminescence layer, wherein
the first conductive layer has a first terminal part which is positioned at an outer side of the organic electroluminescence layer and connected to an external power source,
the second conductive layer has a second terminal part which is positioned at an outer side of the organic electroluminescence layer and connected to an external power source,
the first organic insulating layer is disposed at a lower side of the first terminal part via the inorganic insulating layer,
the second organic insulating layer is disposed at a lower side of the second terminal part via the inorganic insulating layer, and
respective inner end faces and respective upper faces of the first organic insulating layer and the second organic insulating layer are covered with the inorganic insulating layer.

2. The organic electroluminescence device according to claim 1, wherein the first organic insulating layer and the second organic insulating layer each are independently disposed on the conductive substrate.

3. The organic electroluminescence device according to claim 1, wherein the inorganic insulating layer further covers respective outer end faces of the first organic insulating layer and the second organic insulating layer.

4. The organic electroluminescence device according to claim 1, wherein the first conductive layer is an anode layer and the second conductive layer is a cathode layer.

5. The organic electroluminescence device according to claim 1, wherein the inorganic insulating layer contains at least one kind of a metal and a semimetal, and at least one kind of the metal and the semimetal is selected from the group consisting of an oxide, a nitride, a carbide, a nitride oxide, a carbide oxide, a carbide nitride, and a carbide nitride oxide.

6. The organic electroluminescence device according to claim 1, wherein the first organic insulating layer and the second organic insulating layer contain at least one kind selected from the group consisting of an acrylic resin, a norbornene resin, an epoxy resin, and a polyimide resin.
